(19) United States
(12) Patent Application Publication
(10) Pub. No.: US 2002/0043681 A1
(43) Pub. Date: Apr. 18, 2002

(54) Hole-type storage cell structure and method for making the structure

(76) Inventors: Robert Tsu, Plano, TX (US); Ming Yang, Richardson, TX (US)

Correspondence Address: TEXAS INSTRUMENTS INCORPORATED, P O BOX 655474, M/S 3999, DALLAS, TX, 75265

(21) Appl. No.: 09/828,824

(22) Filed: Apr. 10, 2001

Related U.S. Application Data
(62) Division of application No. 09/399,845, filed on Sep. 21, 1999.
(60) Provisional application No. 60/102,317, filed on Sep. 29, 1998.

(51) Int. Cl. H01L 29/76; H01L 29/94; H01L 21/8234

(52) U.S. Cl. 257/301; 257/296; 438/238; 438/243; 257/309; 438/255

(57) ABSTRACT

An embodiment of the instant invention is a semiconductor device having at least two memory cells fabricated over a semiconductor substrate, the semiconductor device comprising: a first memory cell comprised of a bottom electrode having a bottom portion (230) and a vertical portion (232) and a capacitor dielectric (219); a second memory cell comprised of a bottom electrode having a bottom portion (230) and a vertical portion (232) and the capacitor dielectric (219); a pillar of insulating material (214) situated between the vertical portion of the first memory device and the vertical portion of the second memory cell; and wherein the capacitor dielectric extends along the vertical portion and the bottom portion of the first memory cell, the vertical portion and the bottom portion of the second memory cell, and on top of the pillar of insulating material. Preferably, the pillar of insulating material is comprised of: silicon dioxide, BPSG, PSG, PETEOS, TEOS, xerogel, aerogel, HSQ, or a combination thereof. The pillar of insulating material, preferably, abuts the vertical portion of the first memory cell and the vertical portion of the second memory cell, and it prevents the capacitor dielectric from being situated between the vertical portion of first memory cell and the vertical portion of the second memory cell.

### CROSS-REFERENCE TO RELATED PATENT/PATENT APPLICATIONS

The following commonly assigned patent/patent applications are hereby incorporated herein by reference:

| Pat. No./Ser. No. | Filing Date | TI Case No. |
|---|---|---|
| | **/**/1996 | TI-21704 |
| | | TI-23370 |

### FIELD OF THE INVENTION

The instant invention pertains to semiconductor device fabrication and processing and more specifically to a method of fabricating and a structure for a memory cell.

### BACKGROUND OF THE INVENTION

It is a generally desirable goal in semiconductor fabrication to reduce the size of semiconductor devices. This holds true for semiconductor memory devices such as Dynamic Random Access Memory (DRAM) devices. As semiconductor memory device dimensions continue to shrink, and the corresponding density continues to increase by a 4×rule, the storage cell gets increasingly smaller while the required storage charge remains about the same. Conventional oxynitride (N/O or O/N/O) dielectrics have a relatively low capacitance per unit area (˜7.7 fF/um2, for an effective oxide thickness of 4.5 nm) that limits the storage capacity because of potential high tunneling leakage. To combat this problem, various area enhancement techniques have been proposed, including hemispherical grain (HSG) rugged poly, disks, fin, and corrugated cylindrical cell (CCC). However, these area enhancement techniques have inherent limitations.

The HSG technique requires complicated deposition processes within a narrow temperature window. Storage cells that incorporate fins, disks, and CCC formations are primarily composed of multiple horizontal fins. As the storage cell size is further decreased, the fins add less surface area than vertical sidewalls. Furthermore, the typical fin-type structure fabrication is not a robust manufacturing process, and results in a storage cell that is not very mechanically stable, especially during oxide removal between horizontal fins and particle removal.

In another attempt to overcome the limitations of conventional oxynitride dielectrics, high dielectric constant materials, including Ta₂O₅, Ba₁₋ₓSrxTiO₃ (BST), SrTiO₃, and Pb₁₋ₓZrₓTiO₃ (PZT), have been proposed as storage dielectrics due to their high capacitance per unit area. The high capacitance per unit area could theoretically allow use of a simple stacked cell storage cell structure. However, high dielectric constant materials are new to semiconductor fabrication and several obstacles exist to implementation in semiconductor fabrication, including contamination to transistors, robust deposition process development, etching of the new materials, integration experience, and reliability.

### SUMMARY OF THE INVENTION

One embodiment of the instant invention is a new memory structure which will, preferably, be more stable when fabricated than cells using existing techniques. Another embodiment of the instant invention is a method of fabricating this improved memory cell.

An embodiment of the instant invention is a semiconductor device having at least two memory cells fabricated over a semiconductor substrate, the semiconductor device comprising: a first memory cell comprised of a bottom electrode having a bottom portion and a vertical portion and a capacitor dielectric; a second memory cell comprised of a bottom electrode having a bottom portion and a vertical portion and the capacitor dielectric; a pillar of insulating material situated between the vertical portion of the first memory device and the vertical portion of the second memory cell; and wherein the capacitor dielectric extends along the vertical portion and the bottom portion of the first memory cell, the vertical portion and the bottom portion of the second memory cell, and on top of the pillar of insulating material. Preferably, the pillar of insulating material is comprised of: silicon dioxide, BPSG, PSG, PETEOS, TEOS, xerogel, aerogel, HSQ, or a combination thereof. The pillar of insulating material, preferably, abuts the vertical portion of the first memory cell and the vertical portion of the second memory cell, and it prevents the capacitor dielectric from being situated between the vertical portion of first memory cell and the vertical portion of the second memory cell.

Another embodiment of the instant invention is a method of fabricating an electronic device having a memory cell situated above a semiconductor substrate, the method comprising the steps of: forming a layer of first insulating material over the semiconductor substrate, the layer of first insulating material having a top surface; forming conductive contacts in the first layer of insulating material, the conductive contacts having a top portion which extends to the top surface of the layer of first insulating material; forming a layer of second insulating material over the layer of first insulating material, the layer of second insulating material having openings which have sidewalls and a bottom which expose the top portion of the conductive contacts; and forming a bottom electrode of the memory cell by forming a layer of conductive material on the sidewalls and bottom of the openings of the layer of second insulating material, the bottom electrode making electrical contact to the top portion of the conductive contact. Preferably, the conductive material is comprised of: doped polysilicon, silicide, titanium nitride, tungsten, tungsten nitride, cobalt, and any combination thereof, and the layer of second insulating material is comprised of: PSG, BPSG, PETEOS, TEOS, an oxide, HSQ, and a combination thereof. The conductive material is, preferably, comprised of the same material as the conductive contacts.

### BRIEF DESCRIPTION OF THE DRAWINGS

FIG. 1 is a cross-sectional view of a partially fabricated memory device. FIG. 1 illustrates the first gate structures situated over a semiconductor substrate.

FIGS. 2a-2f are cross-sectional views of a partially fabricated memory device. FIGS. 2a-2f are taken from a plane transverse to FIG. 1. Tis is illustrated by the A-A line (which represents the plane in which FIGS. 2a-2f were taken) in FIG. 1. FIGS. 2a-2f illustrate the method of fabricating and the memory cell structure of the instant invention.

Common reference numerals are used throughout the figures to represent like or corresponding features. The figures are provided to aid the reader in understanding the location of each feature of the instant invention but these figures are not drawn to scale.

### DETAILED DESCRIPTION OF THE DRAWINGS

Most semiconductor manufacturers fabricate memory cells for memory devices, such as DRAMs, by forming the horizontal portion of the bottom plate of the memory cell and then building up the vertical portions from there. However, this is very problematic because there does not exist a good structural support structure to hold these features together and to hold them on to the wafer. Hence, in the processing steps following the formation of the vertical portions of the bottom electrode but prior to the formation of the top electrode, these vertical structures are vulnerable to damage and the entire bottom electrode structure is very susceptible to pulling away from the wafer because there is very little structure holding the vertical portions to the horizontal portion and holding the horizontal portion to the layer it sit on.

In light of this, the method of the instant invention was developed so as to provide of the necessary physical support for the bottom electrode prior to the formation of the top electrode. The memory cell of the instant invention provides better physical support to the vertical portions 232 of the memory cell and it is less susceptible to the pealing away of the bottom portion 230 from contact 207.

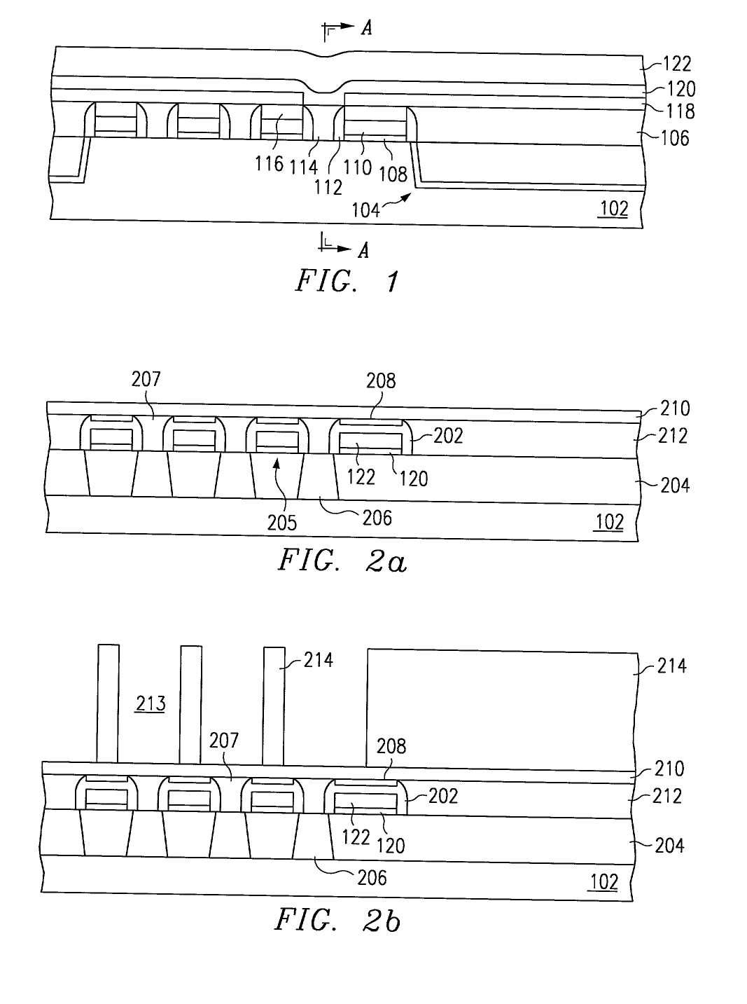

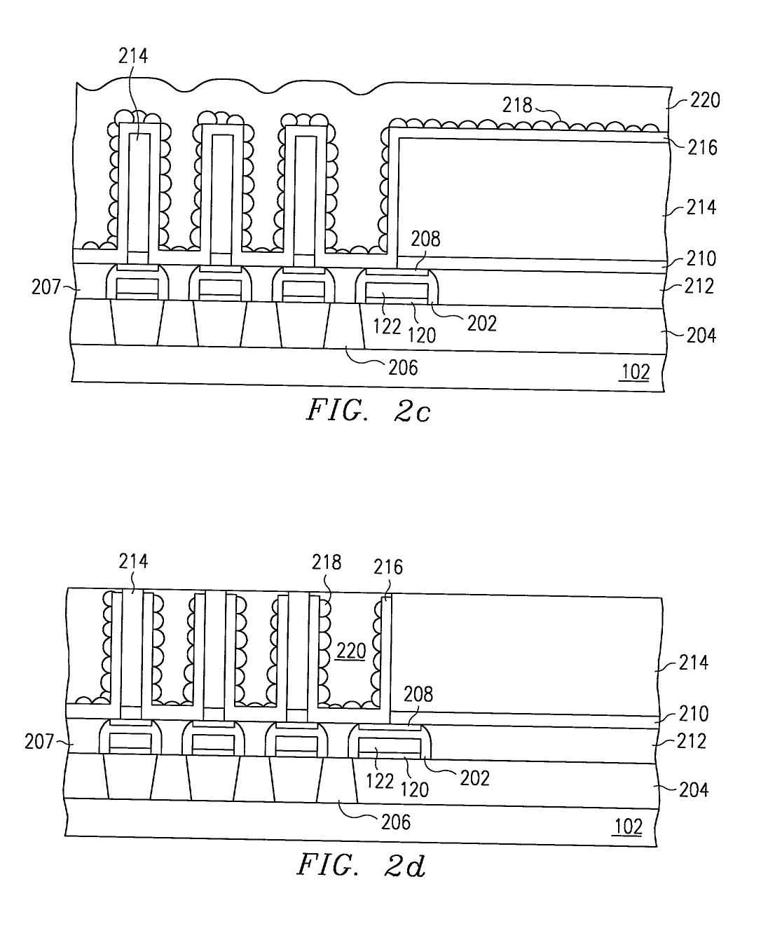

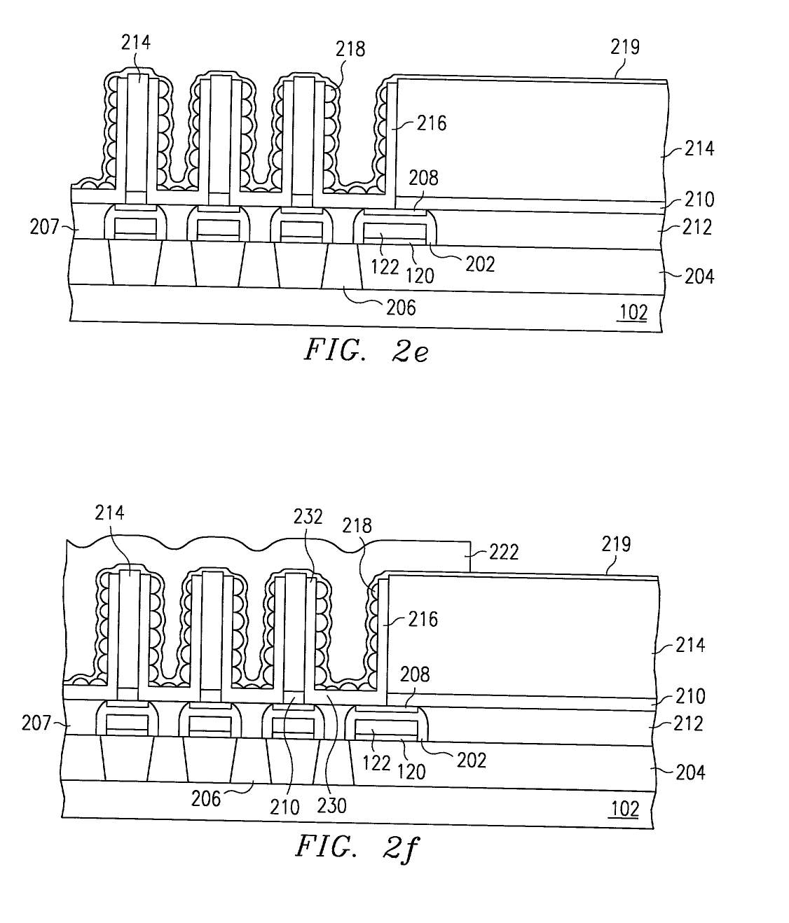

While the following description of the instant invention is centered around FIGS. 1 and 2a-2f, other embodiments will become readily apparent to one of ordinary skill in the art with reference to the instant specification and drawings. For example, these figures illustrate an area enhancement feature 218 which looks like hemispherical grain polycrystalline silicon (HSG), however any type of area enhancement technique can be utilized to form the memory cells of the instant invention. In fact, an area enhancement technique does not even have to be used at all. In addition, these figures also illustrate the memory cell of the instant invention being formed over the bitlines (commonly referred to as capacitor over bitline—“COB”), but this does not have to be the case since the instant invention can be formed under the bitline (BL).

FIG. 1 and the structures underlying the storage cells of FIGS. 1 and 2a-2f are provided for illustrative purposes and any standard type of structures can be used instead of the illustrated structures. FIG. 1 is taken in a plane in which most drawings of a memory device is taken. However, the instant invention is best illustrated in a plane perpendicular to the plane of FIG. 1. In view of his, FIG. 1 is provided so as to orient the reader with respect to the standard figures of memory devices. FIGS. 2a-2f are taken from a plane perpendicular to FIG. 1. This is illustrated in FIG. 1 by line A-A.

to Referring to FIG. 1, isolation structures 104 are formed in semiconductor structure 102. Preferably, semiconductor structure 102 is comprised of single crystal silicon, but it may also be comprised of an epitaxial silicon layer grown on top of a single-crystal silicon substrate. Isolation structures 104 may be comprised of shallow trench isolation structures (shown in FIG. 1), LOCOS regions, trench isolation structures or any other type of isolation structure that is commonly used in the semiconductor industry. Gate structures are formed between isolation structures 104. These gates are commonly referred to as “first gate” (FG) and is comprised of gate insulator 108, sidewall insulators 112, gate electrode 110, and capping insulator 116. Preferably, gate insulator is comprised of silicon dioxide, silicon nitride, a higher dielectric constant material, or a combination of the above; the sidewall insulators are comprised of silicon nitride or silicon dioxide; the gate electrode is comprised of polycrystalline silicon (polysilicon), tungsten, cobalt, titanium, titanium nitride, a combination of any of the above or polysilicon with a titanium or tungsten silicide formed on top; and the capping insulator may be formed of the same material or a different one, but is preferably silicon nitride or silicon dioxide. Regions 106 are, preferably, formed of an insulating material (preferably BPSG, PSG, silicon dioxide, PETEOS, or HSQ) and are planarized using chemical-mechanical polishing. An insulating material, preferably comprised of SiO₂ or S₃N₄, is formed over the planarized structure and an opening is formed in insulating material 118 so that a contact can be made to moat contact 114 (MCNT). Preferably, MCNT 114 is comprised of doped polysilicon, W, Ti, TiN, silicided polysilicon or a combination of the above. A conductive material 120 is formed over insulator 118 and it will make electrical contact with MCNT 114. Conductor 120 is preferably comprised of TiN, but it may be comprised of Ti/TiN, W, tungsten nitride, doped polysilicon, or a combination of the above. Bitline 122 is formed over conductor 120 and is, preferably, comprised of doped polysilicon, W, TiN, silicided polysilicon or a combination of the above. Note that conductor 120 and BL 122 are also illustrated in FIGS. 2a-2f.

Referring to FIG. 2a, a layer of insulating material 204 is provided on substrate 102. Preferably, insulating material 204 is comprised of silicon dioxide, PETEOS, BPSG, PSG, or TEOS. Insulating material 204 is the same layer as insulating material 106. Contacts 206 are formed within the layer of insulating material 204 and are, preferably, comprised of doped polysilicon, tungsten, tungsten nitride, titanium, titanium nitride, or a combination of the above. Contact 206 are the same structures as contacts 114 of FIG. 1. Bitlines 205 are formed over layer 204 and situated between contacts 206 such that contacts 207 will be situated between BLs and aligned with contacts 206. Preferably, contacts 207 are comprised as the same material(s) as contacts 206 but this does not have to be the case. BLs 205 are comprised of an underlying conductive layer 120, conductor 122, insulating sidewalls at top 202 and capping insulator 208. Insulator 202 and capping insulator 208 may be comprised of an oxide, a nitride or an oxynitride. Preferably, insulator 202 and capping insulator 208 are both comprised of silicon nitride, but they may be comprised of different materials. Insulating material 212 lies in the field regions and is preferably comprised of an oxide, PETEOS, TEOS, BPSG, PSG, or even FSG. Bitlines 205 and insulating material are planarized, preferably by CMP, but it is possible to planarize bitlines 205 and use a spun-on material for insulator 212 so as to obtain a planar structure. Next, stopping layer 210 is formed. Preferably, layer 210 is comprised of nitride because silicon nitride acts as a good CMP stopping layer. However, any type of insulating material can be used so long as it acts as a good stopping layer for a subsequent CMP process.

Referring to FIG. 2b, a thick (preferably on the order of 800 to 1500 nm thick) insulating layer is blanketly formed. The thickness of his layer is dependent upon the capacitance required for the storage structures. If a higher capacitance is required, the material should be thicker because it will cause vertical potions 232 of the capacitor to be higher thereby making the capacitor area greater. Preferably, the insulating layer is formed such that it will be substantially planar as it is formed, but a planarization step may be performed after the insulating layer is formed. The insulating material may be comprised of PETEOS, TEOS, an oxide, BPSG, PSG, FSG or a stack of any of the above. Next, the insulating layer is patterned and etched so as to form openings 213, which are aligned to contacts 207, in patterned insulator 214. Openings 213 will be used to form the vertical structures of the bottom electrode of the storage capacitor and the pillars of insulating material between openings 213 will provide support for these structures. Please note, that while these portions of insulating layer 214 look like pillars, they actually form a honeycomb type structure where each of these pillars are connected. It is important to remember, that openings 213 in layer 214 are formed by etching cylindrical openings, which may have a circular, oval, or other cross-sectional shape, in layer 214. Therefore, unless the openings accidentally overlap one another, the portions between these openings will all be interconnected in what will look to be a honeycomb type shape if looked at from above.

Referring to FIG. 2c, exposed portions of stopping layer 210 are removed so as to expose the contacts 207 and portions of the insulating regions surrounding the BLs. Preferably, this is accomplished using a timed etch with little or no overetch if insulating structures 202 and/or 208 are comprised of the same material as layer 210 (preferably all of them will be comprised of silicon nitride). Conductive material 216 is formed, next. Conductor 216 will form the bottom electrode of the storage capacitor and is, preferably, comprised of the same material as contact 207 (preferably doped polysilicon, tungsten, tungsten nitride, titanium nitride, platinum, ruthenium, RuO₂, rhodium, or iridium). If conductive layer 207 is comprised of doped polysilicon an area enhancement technique 218 may be used such as rugged poly, HSG, or other technique. A material which will provide structural support during a subsequent CMP step and is easily removed without damaging the existing structure is formed next in the openings and on the rest of the wafer. Material 220 is preferably comprised of PSG, but it may be comprised of BPSG, an oxide, a flowable oxide (such as HSQ or xerogel), FSG, PETEOS, TEOS, or any other material that fits the above requirements.

Referring to FIG. 2d, a planarization step is performed next so as to remove the portions of conductor which lie on insulating layer 214 (that includes both the field portions and the pillar portions). Otherwise, the bottom plate of all the storage capacitors will be tied together thereby making one large capacitor instead of several smaller and separate storage cells. Preferably, the planarization is accomplished using CMP where this step is terminated upon reaching the top of layer 214 or shortly thereafter. The result of this step should look like FIG. 2d where the only portion of conductor 216 and 218 that remains are along the sidewalls and bottom of the depressions in insulating layer 214. The portions of material 220 that remain in these depressions provide structural support to the vertical and horizontal portions of bottom electrode 216/218. This is one of the many advantages of the instant invention that is not realized in the prior art methods/structures.

Referring to FIG. 2e, the remaining portions of material 220 are selectively removed. In light of this step, it is preferable that material 220 be comprised of a material which is etched by an etchant which does not substantially etch insulating region 214, surface enhance layer 218 (if used) or conductor 216. If material 220 is comprised of a material with a lower dielectric constant, it is important that substantially all of material 220 is removed prior to forming the capacitor dielectric material because the presence of a layer of material 220 on the bottom electrode will decrease the capacitance of the storage cells by a fairly substantial amount. Once material 220 is removed, capacitor dielectric 219 is formed. Capacitor dielectric 219 is preferably comprised of a material that has a higher dielectric constant and that can provide good leakage properties when it is fabricated in a thin layer. Examples of such materials include: oxynitrides, an oxide/nitride stack, a nitride, Ta₂Or, BST, PZT, silicates, or SrTiO₃.

Referring to FIG. 2f, the top electrode of the storage cell is formed, next. Preferably, this is accomplished by blanketly depositing a conductive material and then etching back the material which lies over the field portion of insulating layer 214 (see structure 222). Top electrode 222 may be comprised of doped polysilicon (which may or may not be silicided), tungsten, tungsten nitride, titanium nitride, platinum, ruthenium, rhodium, or iridium and is, preferably, thick enough to fill the depressions formed within layer 214. In fact, top electrode 222 preferably extends far enough over layer 214 so that an interconnect may make contact with it.

Further processing of the device can be accomplished using standard processing techniques. While specific materials were given above for various structures, one of ordinary skill in the art will be able to substitute other materials for those listed based on the teachings with this specification.

Although specific embodiments of the present invention are herein described, they are not to be construed as limiting the scope of the invention Many embodiments of the present invention will become apparent to those skilled in the art in light of methodology of the specification. The scope of the invention is limited only by the claims appended.

What we claim is:

1. A semiconductor device having at least two memory cells fabricated over a semiconductor substrate, said semiconductor device comprising:
a first memory cell comprised of a bottom electrode having a bottom portion and a vertical portion and a capacitor dielectric;
a second memory cell comprised of a bottom electrode having a bottom portion and a vertical portion and said capacitor dielectric;
a pillar of insulating material situated between the vertical portion of said first memory device and the vertical portion of said second memory cell;
and wherein said capacitor dielectric extends along said vertical portion and said bottom portion of said first memory cell, said vertical portion and said bottom portion of said second memory cell, and on top of said pillar of insulating material

2. The method of claim 1, wherein said pillar of insulating material is comprised of a material selected from the group consisting of: silicon dioxide, BPSG, PSG, PETEOS, TEOS, xerogel, aerogel, HSQ, or a combination thereof

3. The method of claim 1, wherein said pillar of insulating material abuts said vertical portion of said first memory cell and said vertical portion of said second memory cell

4. The method of claim 1, wherein said pillar of insulating material prevents said capacitor dielectric from being situated between said vertical portion of first memory cell and said vertical portion of said second memory cell.

5. A method of fabricating an electronic device having a memory cell situated above a semiconductor substrate, said method comprising the steps of:
forming a layer of first insulating material over said semiconductor substrate, said layer of first insulating material having a top surface;
forming conductive contacts in said first layer of insulating material, said conductive contacts having a top portion which extends to said top surface of said layer of first insulating material;
forming a layer of second insulating material over said layer of first insulating material, said layer of second insulating material having openings which have sidewalls and a bottom which expose said top portion of said conductive contacts; and
forming a bottom electrode of said memory cell by forming a layer of conductive material on said sidewalls and bottom of said openings of said layer of second insulating material, said bottom electrode making electrical contact to said top portion of said conductive contact.

6. The method of claim 5, wherein said conductive material is comprised of a material selected from the group consisting of: doped polysilicon, silicide, titanium nitride, tungsten, tungsten nitride, cobalt, and any combination thereof

7. The method of claim 5, wherein said layer of second insulating material is comprised of a material selected from the group consisting of: PSG, BPSG, PETEOS, TEOS, an oxide, HSQ, and a combination thereof.

8. The method of claim 5, wherein said conductive material is comprised of the same material as said conductive contacts.
